(19) United States
(12) Patent Application Publication
(10) Pub. No.: US 2013/0071986 A1
(43) Pub. Date: Mar. 21, 2013

(54) PARTIAL ETCH OF DRAM ELECTRODE

(71) Applicants: Wim Deweerd, San Jose, CA (US); Art Gevondyan, San Francisco, CA (US); Hiroyuki Ode, Higashihiroshima (JP)

(72) Inventors: Wim Deweerd, San Jose, CA (US); Art Gevondyan, San Francisco, CA (US); Hiroyuki Ode, Higashihiroshima (JP)

(73) Assignees: ELPIDA MEMORY, INC., Tokyo (JP); INTERMOLECULAR, INC., San Jose, CA (US)

(21) Appl. No.: 13/234,381

(22) Filed: Sep. 16, 2011

(51) Int. Cl. H01L 21/02

(52) U.S. Cl. 438/396; 438/663; 257/E21.011; 257/E21.008

(57) ABSTRACT

A method for fabricating a dynamic random access memory (DRAM) capacitor stack is disclosed wherein the stack includes a first electrode, a dielectric layer, and a second electrode. The first electrode is formed from a conductive binary metal compound and the conductive binary metal compound is first etched and then annealed in a reducing atmosphere or an inert atmosphere to promote the formation of a desired crystal structure and to remove oxygen rich compounds. The binary metal compound may be a metal oxide. Etching the metal oxide (i.e. molybdenum oxide) may result in the removal of oxygen rich phases and the formation of a first electrode material (i.e. MoO₂) with a rutile-phase crystal structure. This facilitates the formation of the rutile-phase crystal structure when TiO₂ is used as the dielectric layer.

This document relates to the subject matter of a joint research agreement between Intermolecular, Inc. and Elpida Memory, Inc.

### FIELD OF THE INVENTION

The present invention generally relates to the field of dynamic random access memory (DRAM), and more particularly to electrode processing for improved DRAM performance.

### BACKGROUND OF THE INVENTION

Dynamic Random Access Memory utilizes capacitors to store bits of information within an integrated circuit. A capacitor is formed by placing a dielectric material between two electrodes formed from conductive materials. A capacitor's ability to hold electrical charge (i.e., capacitance) is a function of the surface area of the capacitor plates A, the distance between the capacitor plates d, and the relative dielectric constant or k-value of the dielectric material. The capacitance of is given by:

$$C = {κɛ}_{o} \frac{A}{d} \qquad ( Eqn . 1 )$$

where εₒ represents the vacuum permittivity.

The dielectric constant is a measure of a material's polarizability. Therefore, the higher the dielectric constant of a material, the more charge the capacitor can hold. Therefore, if the k-value of the dielectric is increased, the area of the capacitor can be decreased and maintain the desired cell capacitance. Reducing the size of capacitors within the device is important for the miniaturization of integrated circuits. This allows the packing of millions (mega-bit (Mb)) or billions (giga-bit (Gb)) of memory cells into a single semiconductor device. The goal is to maintain a large cell capacitance (generally ˜10 to 25 fF) and a low leakage current (generally <10⁻⁷ A cm⁻²). The physical thickness of the dielectric layers in DRAM capacitors could not be reduced unlimitedly in order to avoid leakage current caused by tunneling mechanisms which exponentially increases as the thickness of the dielectric layer decreases.

Traditionally, SiO₂ has been used as the dielectric material and semiconducting materials (semiconductor-insulator-semiconductor [SIS] cell designs) have been used as the electrodes. The cell capacitance was maintained by increasing the area of the capacitor using very complex capacitor morphologies while also decreasing the thickness of the SiO₂ dielectric layer. Increases of the leakage current above the desired specifications have demanded the development of new capacitor geometries, new electrode materials, and new dielectric materials. Cell designs have migrated to metal-insulator-semiconductor (MIS) and now to metal-insulator-metal (MIM) cell designs for higher performance.

Typically, DRAM devices at technology nodes of 80 nm and below use MIM capacitors wherein the electrode materials are metals. These electrode materials generally have higher conductivities than the semiconductor electrode materials, higher work functions, exhibit improved stability over the semiconductor electrode materials, and exhibit reduced depletion effects. The electrode materials must have high conductivity to ensure fast device speeds. Representative examples of electrode materials for MIM capacitors are metals, conductive metal oxides, conductive metal silicides, conductive metal nitrides (i.e. TiN), or combinations thereof. MIM capacitors in these DRAM applications utilize insulating materials having a dielectric constant, or k-value, significantly higher than that of SiO₂ (k=3.9). For DRAM capacitors, the goal is to utilize dielectric materials with k values greater than about 40. Such materials are generally classified as high-k materials. Representative examples of high-k materials for MIM capacitors are non-conducting metal oxides, non-conducting metal nitrides, non-conducting metal silicates or combinations thereof. These dielectrics may also include additional dopant materials.

A figure of merit in DRAM technology is the electrical performance of the dielectric material as compared to SiO₂ known as the Equivalent Oxide Thickness (EOT). A high-k material's EOT is calculated using a normalized measure of silicon dioxide (SiO₂ k=3.9) as a reference, given by:

$$EOT = \frac{3.9}{κ} \cdot d \qquad ( Eqn . 2 )$$

where d represents the physical thickness of the capacitor dielectric.

As DRAM technologies scale below the 40 nm technology node, manufacturers must reduce the EOT of the high-k dielectric films in MIM capacitors in order to increase charge storage capacity. The goal is to utilize dielectric materials that exhibit an EOT of less than about 0.8 nm while maintaining a physical thickness of about 5-20 nm.

One class of high-k dielectric materials possessing the characteristics required for implementation in advanced DRAM capacitors are high-k metal oxide materials. Titanium dioxide (TiO₂) is one metal oxide dielectric material which displays significant promise in terms of serving as a high-k dielectric material for implementation in DRAM capacitors.

The dielectric constant of a dielectric material may be dependent upon the crystalline phase(s) of the material. For example, in the case of TiO₂, the anatase crystalline phase of TiO₂ has a dielectric constant of approximately 40, while the rutile crystalline phase of TiO₂ can have a dielectric constant of approximately >80. Due to the higher-k value of the rutile-phase, it is desirable to produce TiO₂ based DRAM capacitors with the TiO₂ in the rutile-phase. The relative amounts of the anatase phase and the rutile phase can be determined from x-ray diffraction (XRD). From Eqn. 1 above, a TiO₂ layer in the rutile-phase could be physically thicker and maintain the desired capacitance. The increased physical thickness is important for lowering the leakage current of the capacitor. The anatase phase will transition to the rutile phase at high temperatures (>800 C). However, high temperature processes are undesirable in the manufacture of DRAM devices.

The crystal phase of an underlying layer can be used to influence the growth of a specific crystal phase of a subsequent material if their crystal structures are similar and their lattice constants are similar. This technique is well known in technologies such as epitaxial growth. The same concepts have been extended to the growth of thin films where the underlying layer can be used as a “template” to encourage the growth of a desired phase over other competing crystal phases.

Therefore, there is a need to develop a DRAM electrode which promotes the growth of the rutile-phase in a TiO₂ dielectric layer during formation of the dielectric layer. Such a DRAM electrode would enable a DRAM capacitor with high cell capacitance, small area, low leakage current, and fast device speed.

Generally, as the dielectric constant of a material increases, the band gap of the material decreases. This leads to high leakage current in the device. As a result, without the utilization of countervailing measures, capacitor stacks implementing high-k dielectric materials may experience large leakage currents. High work function electrodes (e.g., electrodes having a work function of greater than 5.0 eV) may be utilized in order to counter the effects of implementing a reduced band gap high-k dielectric layer within the DRAM capacitor. Metals, such as platinum, gold, ruthenium, and ruthenium oxide are examples of high work function electrode materials suitable for inhibiting device leakage in a DRAM capacitor having a high-k dielectric layer. The noble metal systems, however, are prohibitively expensive when employed in a mass production context. Moreover, electrodes fabricated from noble metals often suffer from poor manufacturing qualities, such as surface roughness, poor adhesion, and form a contamination risk in the fab.

Conductive metal oxides, conductive metal silicides, conductive metal nitrides, or combinations thereof comprise other classes of materials that may be suitable as DRAM capacitor electrodes. Generally, transition metals and their conductive binary compounds form good candidates as electrode materials. The transition metals exist in several oxidation states. Therefore, a wide variety of compounds are possible. Different compounds may have different crystal structures, electrical properties, etc. It is important to utilize the proper compound for the desired application.

In one example of materials suitable for use as DRAM capacitor electrodes, molybdenum has several binary oxides of which MoO₂ and MoO₃ are two examples. These two oxides of molybdenum have different properties. MoO₂ is conductive and has shown great promise as an electrode material in DRAM capacitors. MoO₂ has a distorted rutile crystal structure and can serve as an acceptable template to promote the deposition of the rutile-phase of TiO₂ as discussed above. MoO₂ also has a high work function (can be >5.0 eV depending on process history) which helps to minimize the leakage current of the DRAM device. However, oxygen-rich phases (MoO₂₊ₓ) of MoO₂ degrade the performance of the MoO₂ electrode because they act more like insulators and have crystal structures that do not promote the deposition of the rutile-phase of TiO₂. For example, MoO₃ (the most oxygen-rich phase) is a dielectric material and has an orthorhombic crystal structure.

Generally, a deposited thin film may be amorphous, crystalline, or a mixture thereof. Furthermore, several different crystalline phases may exist. The thin film may exhibit different physical, chemical, and structural properties throughout the thickness of the film following deposition. As an example, the top part of the thin film may exhibit different properties from the bottom part of the film. Therefore, processes (both deposition and post-treatment) must be developed to maximize the formation and uniformity through the depth of the film of crystalline MoO₂ and to minimize the presence of MoO₂₊ₓ phases. The MoO₂₊ₓ phases may form during the deposition of the electrode and may not be evenly distributed throughout the layer thickness. The MoO₂ electrode material may be deposited using any common deposition technique such as atomic layer deposition (ALD), plasma enhanced atomic layer deposition (PE-ALD), atomic vapor deposition (AVD), ultraviolet assisted atomic layer deposition (UV-ALD), chemical vapor deposition (CVD), plasma enhanced chemical vapor deposition (PECVD), or physical vapor deposition (PVD). Typically, the MoO₂ electrode material must be annealed after deposition to fully crystallize the film. Even if the anneal is performed under an inert gas such as nitrogen, the presence of MoO₂₊ₓ phases are observed and the effective k-value of the TiO₂ dielectric subsequently deposited on such an electrode is lower than desired.

Therefore, there is a need to develop methods for producing an electrode system that maximize the presence of crystalline conductive metal oxide layers and promote the growth of the high k phase in a subsequently deposited dielectric layer, while simultaneously providing the high work function and manufacturability characteristics required for next generation DRAM capacitors.

### SUMMARY OF THE INVENTION

In some embodiments of the present invention, an etch process is performed after the deposition of the electrode layer but before the electrode layer is annealed. The etch step results in a electrode layer with a higher density after the anneal step. The etch step may be any one of a wet etch technique, a reactive ion etch (RIE) technique, or an ion milling etch technique. The technique may be applied to either the first electrode, the second electrode, or both.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 illustrates a flow chart illustrating a method for fabricating a DRAM capacitor stack, in accordance with some embodiments of the present invention.

FIG. 2 illustrates a flow chart illustrating a method for fabricating a DRAM capacitor stack, in accordance with some embodiments of the present invention.

FIG. 3 illustrates a flow chart illustrating a method for fabricating a DRAM capacitor stack, in accordance with some embodiments of the present invention.

FIG. 4 illustrates a simplified cross-sectional view of a DRAM first electrode layer fabricated in accordance with some embodiments of the present invention.

FIG. 5 illustrates a simplified cross-sectional view of a DRAM capacitor stack fabricated in accordance with some embodiments of the present invention.

FIG. 6 illustrates a simplified cross-sectional view of a DRAM capacitor stack fabricated in accordance with some embodiments of the present invention.

FIG. 7 presents SIMS data illustrating the distribution of Mo and O throughout the depth of the deposited first electrode layer.

FIG. 8 illustrates a simplified cross-sectional view of a DRAM memory cell fabricated in accordance with some embodiments of the present invention.

### DETAILED DESCRIPTION OF THE INVENTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

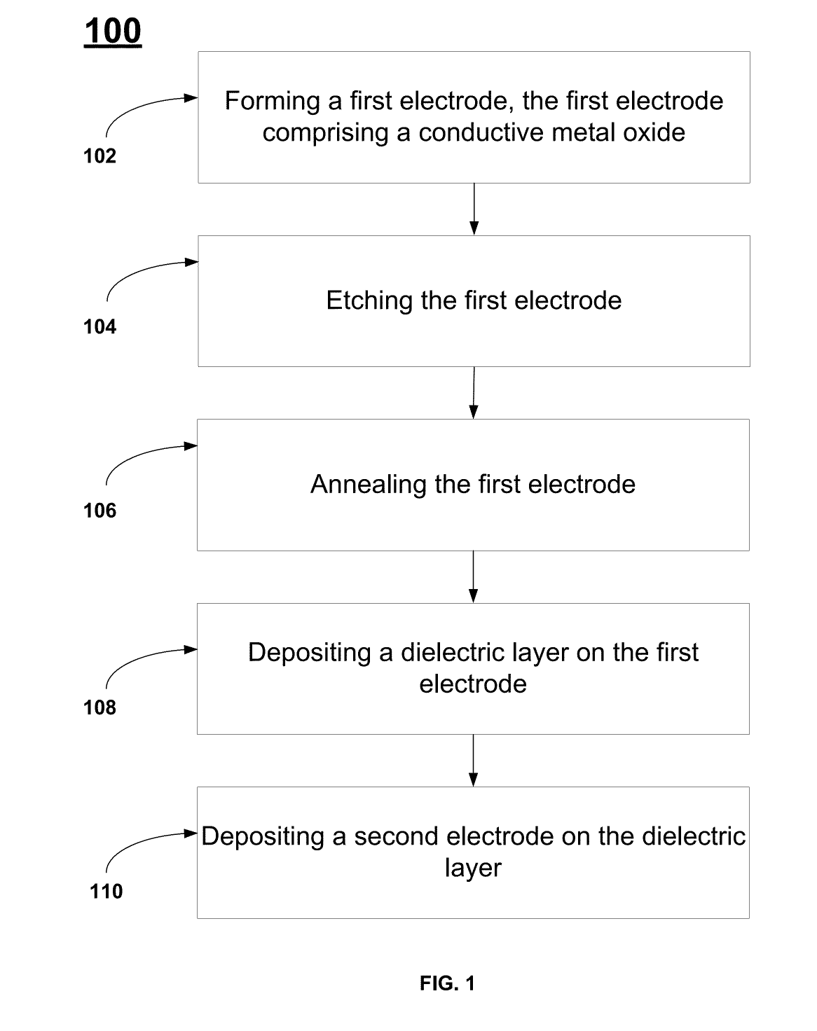

FIG. 1 describes a method, 100, for fabricating a DRAM capacitor stack. The initial step, 102, comprises forming a first electrode layer. Examples of suitable electrode materials comprise conductive metal oxides, conductive metal silicides, conductive metal nitrides, and combinations thereof. A particularly interesting class of materials is the conductive metal oxides. Generally, deposited thin films of these conductive metal oxide materials also contain oxygen-rich components. The next step, 104, comprises etching the surface of the first electrode layer to remove the top portion of the deposited film. Examples of suitable etch techniques comprise wet etch techniques, RIE techniques and ion milling techniques. Examples of suitable wet etch formulations are described in U.S. application Ser. No. 13/165,923 filed on Jun. 22, 2011, entitled “WET ETCH AND CLEAN CHEMISTRIES FOR MoOₓ” and is incorporated herein by reference. The next step, 106, comprises annealing the first electrode layer in a reducing atmosphere or an inert atmosphere (i.e. N₂ or Ar) and decreasing the concentration of the oxygen-rich components. As used herein, a reducing atmosphere is one where oxidation of the electrode is prevented by the presence of gases such as H₂ and NH₃ as a mixture in an inert gas such as N₂ or Ar, etc. Furthermore, surplus oxygen in the metal oxide materials can be removed through reaction with the reducing atmosphere. The annealing in the reducing atmosphere may utilize either thermal energy or plasma energy to activate the reducing atmosphere. The next step, 108, comprises forming a dielectric material on the annealed first electrode layer. Optionally, the dielectric material may undergo a post dielectric anneal (PDA) treatment. The next step, 110, comprises forming a second electrode layer on the dielectric layer. Optionally, the DRAM capacitor stack may undergo a post metallization anneal (PMA) treatment. Examples of the PDA and PMA treatments are further described in U.S. application Ser. No. 13/159,842 filed on Jun. 14, 2011, entitled “METHOD OF PROCESSING MIM CAPACITORS TO REDUCE LEAKAGE CURRENT” and is incorporated herein by reference.

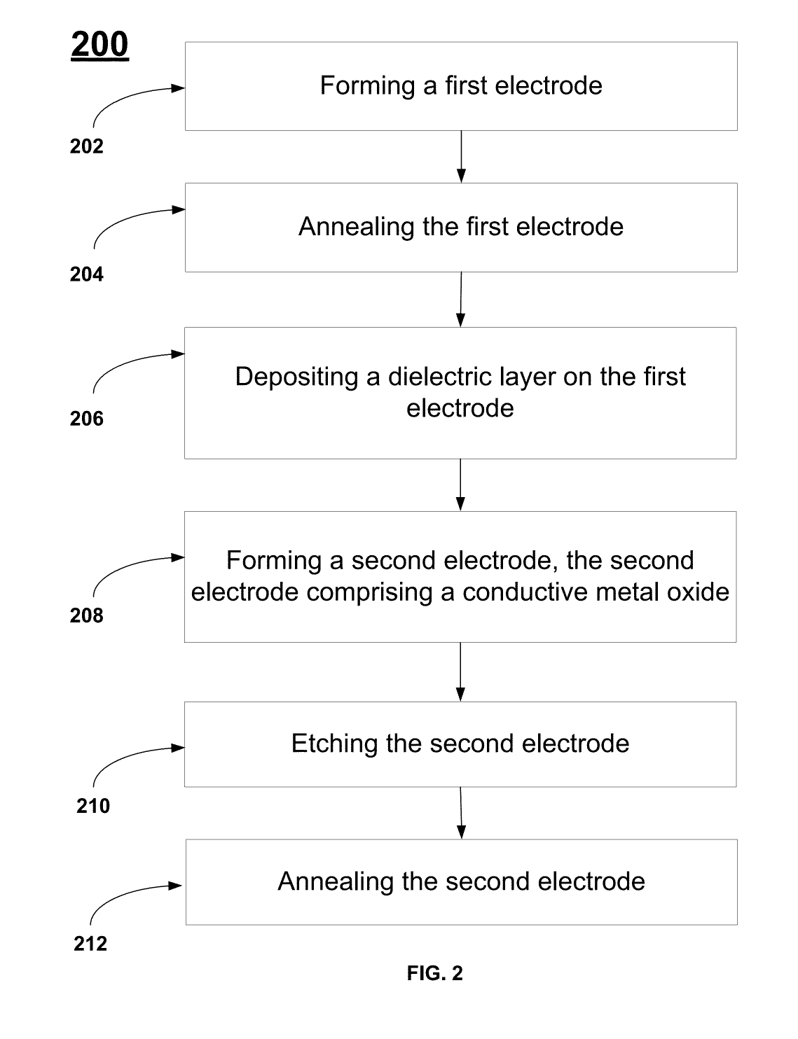

FIG. 2 describes a method, 200, for fabricating a DRAM capacitor stack. The initial step, 202, comprises forming a first electrode layer. Examples of suitable electrode materials comprise conductive metal oxides, conductive metal silicides, conductive metal nitrides, and combinations thereof. A particularly interesting class of materials is the conductive metal oxides. Generally, deposited thin films of these conductive metal oxide materials also contain oxygen-rich components. The next step, 204, comprises annealing the first electrode layer in a reducing atmosphere or an inert atmosphere (i.e. N₂ or Ar) and decreasing the concentration of the oxygen-rich components. As used herein, a reducing atmosphere is one where oxidation of the electrode is prevented by the presence of gases such as H₂ and NH₃ as a mixture in an inert gas such as N₂ or Ar, etc. Furthermore, surplus oxygen in the metal oxide materials can be removed through reaction with the reducing atmosphere. The annealing in the reducing atmosphere may utilize either thermal energy or plasma energy to activate the reducing atmosphere. The next step, 206, comprises forming a dielectric material on the annealed first electrode layer. Optionally, the dielectric material may undergo a post dielectric anneal (PDA) treatment as mentioned previously. The next step, 208, comprises forming a second electrode layer on the dielectric layer. Examples of suitable electrode materials comprise conductive metal oxides, conductive metal silicides, conductive metal nitrides, and combinations thereof. A particularly interesting class of materials is the conductive metal oxides. Generally, deposited thin films of these conductive metal oxide materials also contain oxygen-rich components. The next step, 210, comprises etching the surface of the second electrode layer to remove the top portion of the deposited film. Examples of suitable etch techniques comprise wet etch techniques, RIE techniques and ion milling techniques. Typically, the DRAM capacitor stack may undergo a post metallization anneal (PMA) treatment in step 212 as mentioned previously.

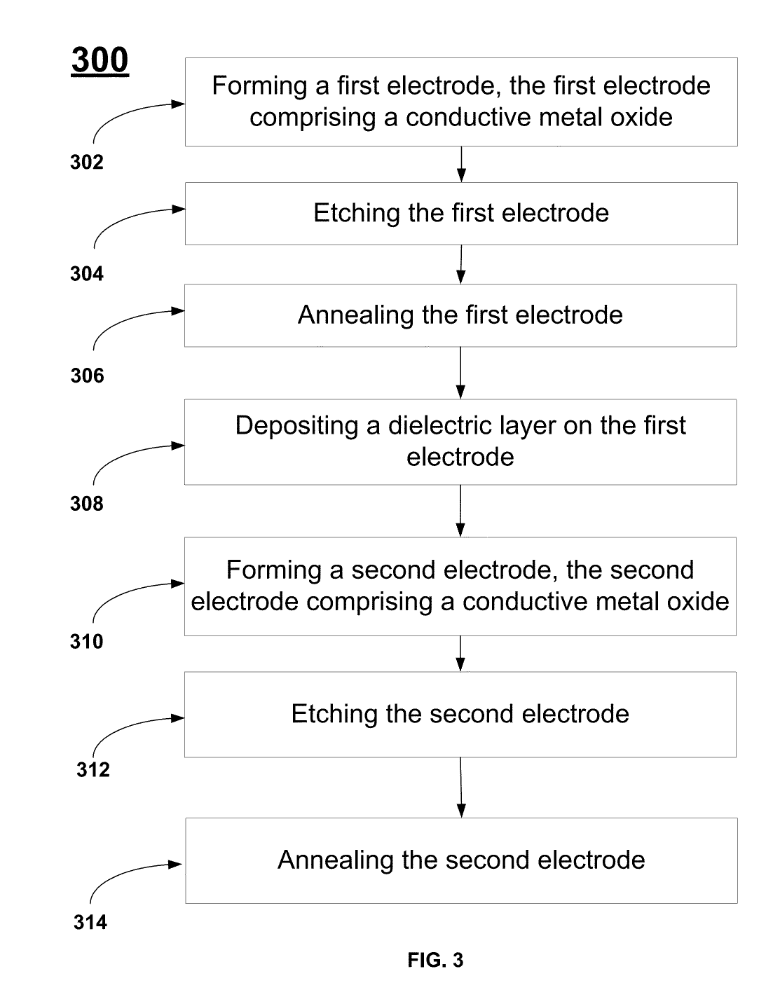

FIG. 3 describes a method, 300, for fabricating a DRAM capacitor stack. The initial step, 302, comprises forming a first electrode layer. Examples of suitable electrode materials comprise conductive metal oxides, conductive metal silicides, conductive metal nitrides, and combinations thereof. A particularly interesting class of materials is the conductive metal oxides. Generally, deposited thin films of these conductive metal oxide materials also contain oxygen-rich components. The next step, 304, comprises etching the surface of the first electrode layer to remove the top portion of the deposited film. Examples of suitable etch techniques comprise wet etch techniques, RIE techniques and ion milling techniques. The next step, 306, comprises annealing the first electrode layer in a reducing atmosphere or an inert atmosphere (i.e. N₂ or Ar) and decreasing the concentration of the oxygen-rich components. As used herein, a reducing atmosphere is one where oxidation of the electrode is prevented by the presence of gases such as H₂ and NH₃ as a mixture in an inert gas such as N₂ or Ar, etc. Furthermore, surplus oxygen in the metal oxide materials can be removed through reaction with the reducing atmosphere. The annealing in the reducing atmosphere may utilize either thermal energy or plasma energy to activate the reducing atmosphere. The next step, 308, comprises forming a dielectric material on the annealed first electrode layer. Optionally, the dielectric material may undergo a post dielectric anneal (PDA) treatment as mentioned previously. The next step, 310, comprises forming a second electrode layer on the dielectric layer. Examples of suitable electrode materials comprise conductive metal oxides, conductive metal silicides, conductive metal nitrides, and combinations thereof. A particularly interesting class of materials is the conductive metal oxides. Generally, deposited thin films of these conductive metal oxide materials also contain oxygen-rich components. The next step, 312, comprises etching the surface of the second electrode layer to remove the top portion of the deposited film. Examples of suitable etch techniques comprise wet etch techniques, RIE techniques and ion milling techniques. Typically, the DRAM capacitor stack may undergo a post metallization anneal (PMA) treatment in step 314 as mentioned previously.

Those skilled in the art will appreciate that each of the first electrode layer, the dielectric layer, and the second electrode layer may be formed using well known techniques such as ALD, PE-ALD, AVD, UV-ALD, CVD, PECVD, or PVD. Generally, because of the complex morphology of the DRAM capacitor structure, ALD, PE-ALD, AVD, or CVD are preferred methods of formation. However, any of these techniques are suitable for forming each of the various layers discussed below. Those skilled in the art will appreciate that the teachings described below are not limited by the technology used for the deposition process.

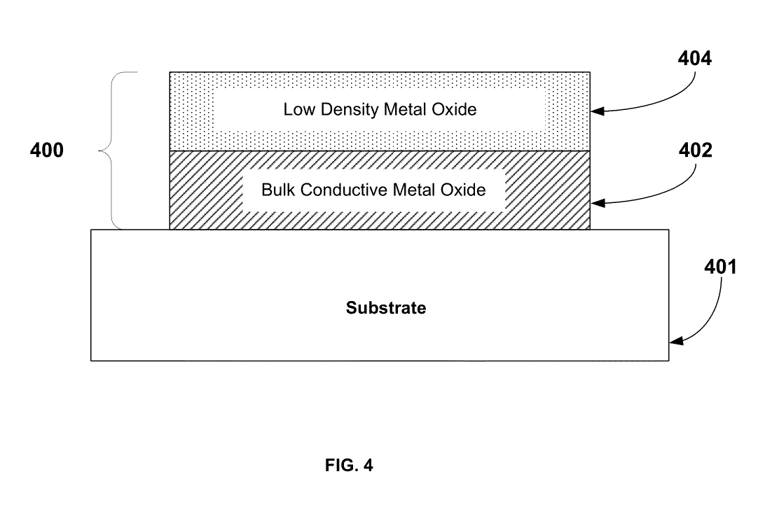

In FIGS. 4, 5, 6 and 8 below, a capacitor stack is illustrated using a simple planar structure. Those skilled in the art will appreciate that the description and teachings to follow can be readily applied to any simple or complex capacitor morphology. The drawings are for illustrative purposes only and do not limit the application of the present invention.

FIG. 4 illustrates a simple capacitor first electrode, 400, consistent with some embodiments of the present invention. Using the method as outlined in FIG. 1 and described above, first electrode layer, 400, is formed on substrate, 401. Generally, the substrate has already received several processing steps in the manufacture of a full DRAM device. First electrode layer, 400, comprises a conductive metal oxide material that also contains oxygen-rich components. Examples of the conductive metal oxides include the conductive compounds of molybdenum oxide, tungsten oxide, ruthenium oxide, rhenium oxide, chromium oxide, rhodium oxide, iridium oxide, manganese oxide, tin oxide, cobalt oxide, or nickel oxide. Illustrated in FIG. 4 is a schematic wherein the first electrode layer, 400, is depicted as having a bulk conductive metal oxide layer, 402, at the bottom portion of the first electrode layer (i.e. at the substrate interface) and a low density metal oxide layer, 404, at the top portion of the first electrode layer. The low density metal oxide layer may be formed at the end of the deposition of the first electrode layer. The low density metal oxide layer may have different structural, chemical, and electrical properties from the underlying bulk conductive metal oxide layer. Typically, the low density metal oxide layer will have a higher resistivity than the bulk conductive metal oxide layer. Molybdenum oxide will be discussed as a specific example, but other metals that form non-conducting or highly resistive oxygen-rich metal oxides (in addition to their desirable conductive metal oxides) such as Ru, Co, etc. will also exhibit this behavior. Although FIG. 4 illustrates a first electrode, the same discussion would hold for a conductive metal oxide used as a second electrode (not shown). The bottom portion of the second electrode (i.e. in contact with the dielectric layer) would be the bulk conductive metal oxide layer and a low density metal oxide layer would form the top portion of the second electrode. As outlined in the methods described in FIG. 2 and FIG. 3, the second electrode can also be subjected to an etch step to remove the low density portion before being annealed.

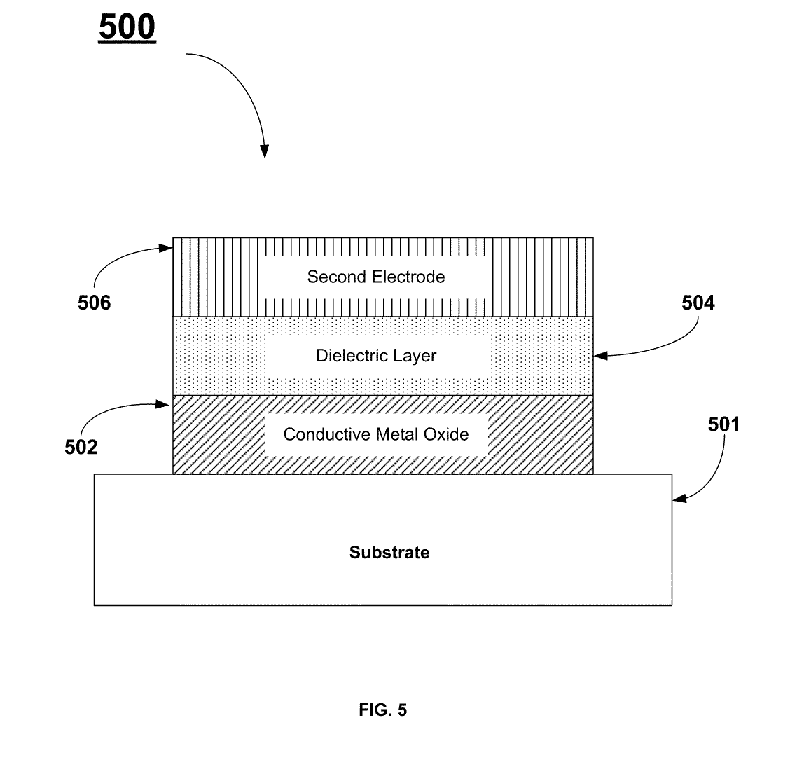

FIG. 5 illustrates a simple capacitor stack, 500, consistent with some embodiments of the present invention. Using the method as outlined in FIG. 1 and described above, first electrode layer, 502, is formed on substrate, 501. Generally, the substrate has already received several processing steps in the manufacture of a full DRAM device. First electrode layer, 502, comprises a conductive metal oxide material that also contains oxygen-rich components. Examples of the conductive metal oxides include the conductive compounds of molybdenum oxide, tungsten oxide, ruthenium oxide, rhenium oxide, chromium oxide, rhodium oxide, iridium oxide, manganese oxide, tin oxide, cobalt oxide, or nickel oxide. First electrode layer, 502, would then be etched as described previously.

In the next step, the substrate with first electrode layer, 500, would then be annealed in a reducing atmosphere or an inert atmosphere (i.e. N₂ or Ar) to reduce the concentration of the oxygen-rich components. Generally, the reducing atmosphere will comprise H₂, or NH₃ mixed with an inert gas. A specific example of a reducing atmosphere that is available commercially is forming gas wherein the H₂ concentration can range between about 1 and 25% mixed with N₂. The annealing in the reducing atmosphere may utilize either thermal energy or plasma energy to activate the reducing atmosphere. Alternatively, the first electrode layer may be annealed using a Rapid Thermal Annealing (RTA) technique wherein the temperature is quickly raised in the presence of a nitrogen containing gas such as N₂, forming gas, NH₃, etc. Examples of the possible annealing treatments are further described in U.S. application Ser. No. 13/084,666 filed on Apr. 12, 2011, entitled “METHOD FOR FABRICATING A DRAM CAPACITOR” and is incorporated herein by reference.

In the next step, dielectric layer, 504, would then be formed on the annealed first electrode layer, 502. A wide variety of dielectric materials have been targeted for use in DRAM capacitors. Examples of suitable dielectric materials comprise SiO₂, a bilayer of SiO₂ and SiₓN_{y}, SiON, Al₂O₃, HfO₂, HfSiOₓ, ZrO₂, Ta₂O₅, TiO₂, SrTiO₃ (STO), BaSrTiOₓ (BST), PbZrTiOₓ (PZT) or doped versions of the same. These dielectric materials may be formed as a single layer or may be formed as a hybrid or nanolaminate structure. A specific dielectric material of interest is the rutile-phase of TiO₂.

In the next step, the second electrode layer, 506, is formed on dielectric layer, 504. The second electrode layer may be a conductive binary metal compound material as described above, a metal, or a combination thereof. FIG. 5 illustrates a conductive metal oxide first electrode, the same discussion would hold for a conductive metal oxide used as a second electrode, 506. The bottom portion of the second electrode (i.e. in contact with the dielectric layer) would be the bulk conductive metal oxide layer and a low density metal oxide layer would form the top portion of the second electrode. As outlined in the methods described in FIG. 2 and FIG. 3, the second electrode can also be subjected to an etch step to remove the low density portion before being annealed. The remaining full DRAM device (not shown) would then be manufactured using well known techniques. Typically, the DRAM capacitor stack may now receive a PMA treatment.

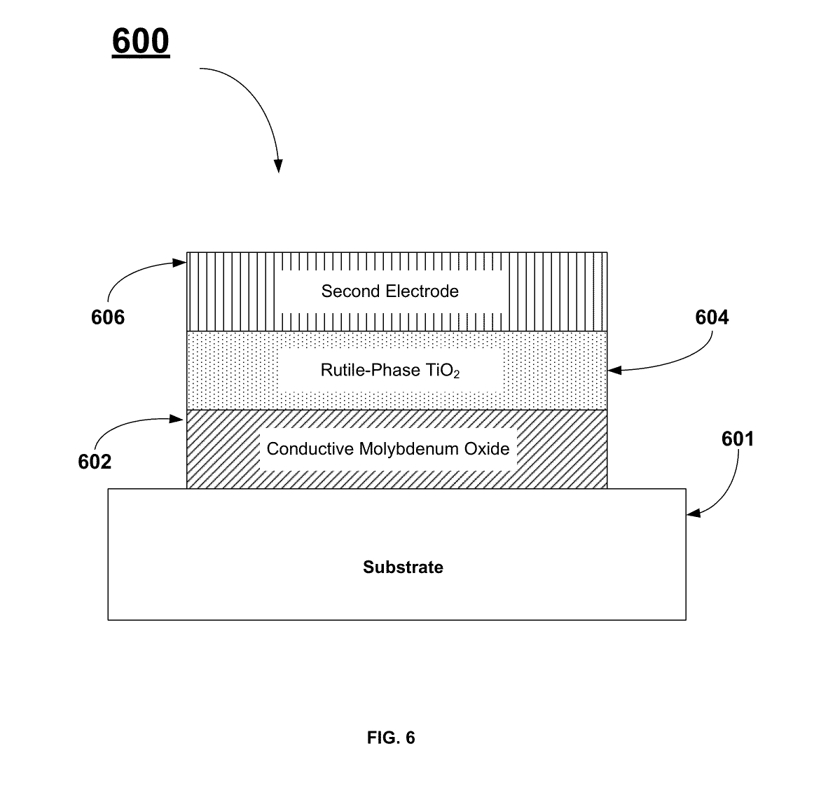

FIG. 6 illustrates a specific example of a simple capacitor stack, 600, consistent with some embodiments of the present invention. Using the method as outlined in FIG. 1 and described above, first electrode layer, 602, is formed on substrate, 601. Generally, the substrate has already received several processing steps in the manufacture of a full DRAM device. First electrode layer, 602, comprises a MoO₂ material that also contains oxygen-rich components (MoO₂₊ₓ). The goal is to maximize the amount of MoO₂ present in first electrode layer, 602, because it is metallic and has a high work function and also has a distorted rutile crystal structure and would serve as a good template to promote the growth of rutile-phase of a TiO₂ dielectric material in a later deposition step. The presence of oxygen-rich materials (MoO₂₊ₓ) is to be minimized because they are poor dielectric materials and generally do not promote the growth of the rutile-phase crystal structure of the TiO₂ dielectric material. First electrode layer, 602, would then be etched as described previously.

In the next step, the substrate with etched first electrode layer, 602, comprising MoO₂ would then be annealed in a reducing atmosphere or an inert atmosphere (i.e. N₂ or Ar) to reduce the concentration of the oxygen-rich components and increase the relative amount of MoO₂ phases. Typically, the annealing step will be performed in a temperature range between about 400 C and about 650 C. Generally, the reducing atmosphere will comprise H₂, or NH₃ mixed with an inert gas. A specific example of a reducing atmosphere that is available commercially is forming gas wherein the H₂ concentration can range between about 1 and 25% mixed with N₂. The annealing in the reducing atmosphere may utilize either thermal energy, plasma energy or RTA to activate the reducing atmosphere. The reducing atmosphere will crystallize the first electrode layer if there is an amorphous component and reduce the MoO₂₊ₓ species to MoO₂. It is desirable that the crystalline MoO₂ phase account for ≧40% of the first electrode.

In the next step, dielectric layer, 604, would then be formed on the annealed first electrode layer, 602. In this example, a layer of TiO₂ that exists predominantly (>30%) in the rutile-phase is formed as the dielectric layer, 604. The rutile-phase of TiO₂ grows preferentially over the anatase-phase due to the distorted rutile-phase crystal structure of the underlying predominantly MoO₂ electrode material. The TiO₂ layer generally has a physical layer thickness between 5 nm and 20 nm and exhibits a k value of >40.

In the next step, the second electrode layer, 606, is formed on dielectric layer, 604. The second electrode layer may be a conductive binary metal compound material as described above, a metal, or a combination thereof. Although FIG. 6 illustrates a conductive metal oxide first electrode, the same discussion would hold for a conductive metal oxide used as a second electrode (not shown). The bottom portion of the second electrode (i.e. in contact with the dielectric layer) would be the bulk conductive metal oxide layer and a low density metal oxide layer would form the top portion of the second electrode. As outlined in the methods described in FIG. 2 and FIG. 3, the second electrode can also be subjected to an etch step to remove the low density portion before being annealed. The remaining full DRAM device (not shown) would then be manufactured using well known techniques.

The effect of the etch step was evaluated through the investigation summarized in Table 1 below. First electrode layers were deposited on a substrate using an ALD technique. The nominal thickness of the as deposited films was in the range of about 30 nm to about 37 nm. The RIE steps were conducted at a power of 250 W for 30 seconds using CHF₃. The ion milling steps were conducted at a power of 250 W for 60 seconds using Ar. The Anneal steps were conducted at a temperature of 525 C for 10 minutes in reducing atmospheres of either H₂/N₂ or H₂/Ar. The anneal atmosphere is listed in the parenthesis in the sequence. The data indicate that the as deposited first electrode comprises a mixture of molybdenum oxide phases including MoO₂, MoO₂₊ₓ and MoO₃. MoO₃ has a bulk density of about 4.7 g/cm³ and is an insulator. MoO₂ has a bulk density of about 6.5 g/cm³ and is a good conductor. As illustrated in the comparison between sequences 1) and 2), the post-anneal density for the etched sample (sequence 1) is close to the bulk density of MoO₂ while the post-anneal density for the sample that was simply annealed in a reducing atmosphere (sequence 2) showed only a modest increase in density after the anneal and the density is closer to that of MoO₃. Additionally, the resistivity for the sample in sequence 2) is very high and is another indication that much of the sample consists of MoO₂₊ₓ phases. The results are similar when comparing sequences 3) and 4) wherein the annealing atmosphere was changed to H₂/Ar. Again, the etched sample (sequence 3) exhibits a high density and low resistivity after the anneal step. The data from sequences 3) and 4) suggest that the H₂/Ar annealing atmosphere may be advantageous over the H₂/N₂ annealing atmosphere. The H₂/Ar annealing atmosphere appears to be more effective at removing any MoO₂₊ₓ phases that might be present. Finally, sequence 5) illustrates that similar results may be obtained by using an ion milling etch step followed by an anneal step in a reducing atmosphere. Similar trends would be expected for wet etch techniques. For example, MoO₂₊ₓ phases are slightly soluble in water while MoO₂ is insoluble in water. Therefore, the MoO₂₊ₓ phases would be preferentially removed during a wet etch step.

TABLE 1

| | | | Post-Anneal |
|---|---|---|---|
| | Pre-Anneal | Post Anneal | Resistivity |
| Sequence | Density (g/cm³) | Density (g/cm³) | (μΩ cm) |
| 1) ALD-RIE- | 3.7 | 6.1 | 814 |
| Anneal (H₂/N₂) | | | |
| 2) ALD-Anneal | 3.7 | 4.6 | 3730 |
| (H₂/N₂) | | | |
| 3) ALD-RIE- | 3.7 | 6.6 | 545 |
| Anneal (H₂/Ar) | | | |
| 4) ALD-Anneal | 3.7 | 4.8 | 825 |
| (H₂/Ar) | | | |
| 5) ALD-Ion Mill- | 3.7 | 6.0 | 832 |
| Anneal (H₂/N₂) | | | |

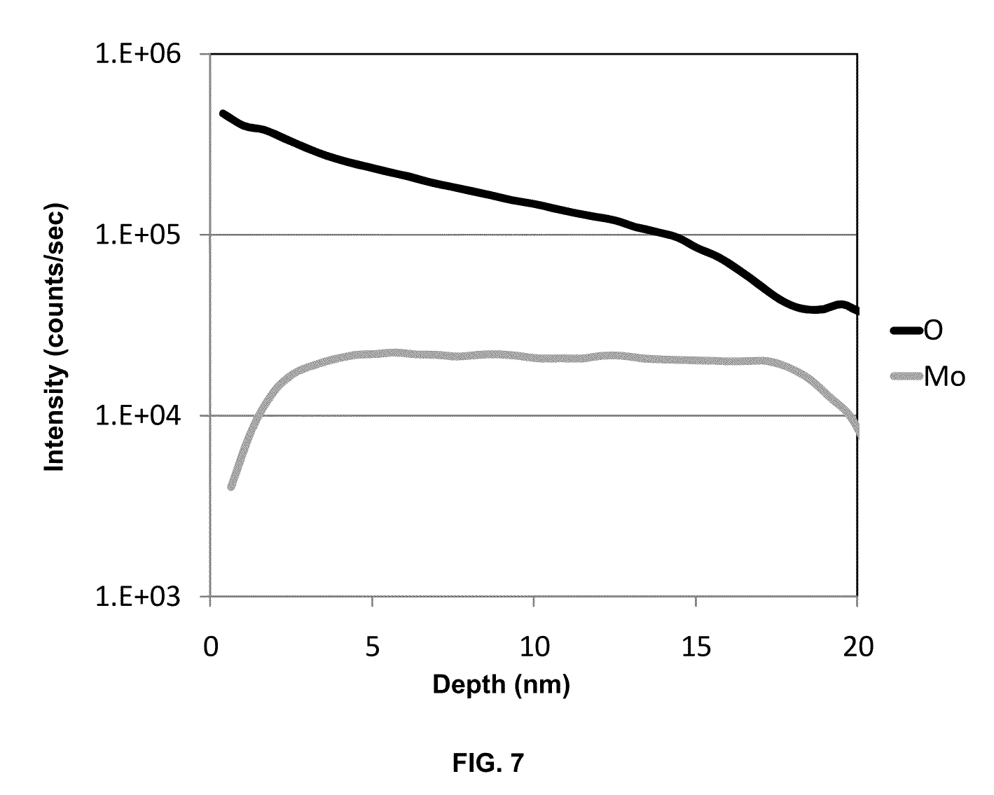

FIG. 7 presents SIMS data illustrating the distribution of Mo and O throughout the depth of the deposited first electrode layer. These data were obtained from an as deposited first electrode sample. The high concentration of oxygen near the surface of the sample indicates that there are oxygen rich MoO₂₊ₓ phases present in the top portion of the film and supports the mechanism discussed previously. The Mo decreases at the surface due to the high concentration of oxygen. As the oxygen concentration increases, the relative amount of Mo decreases.

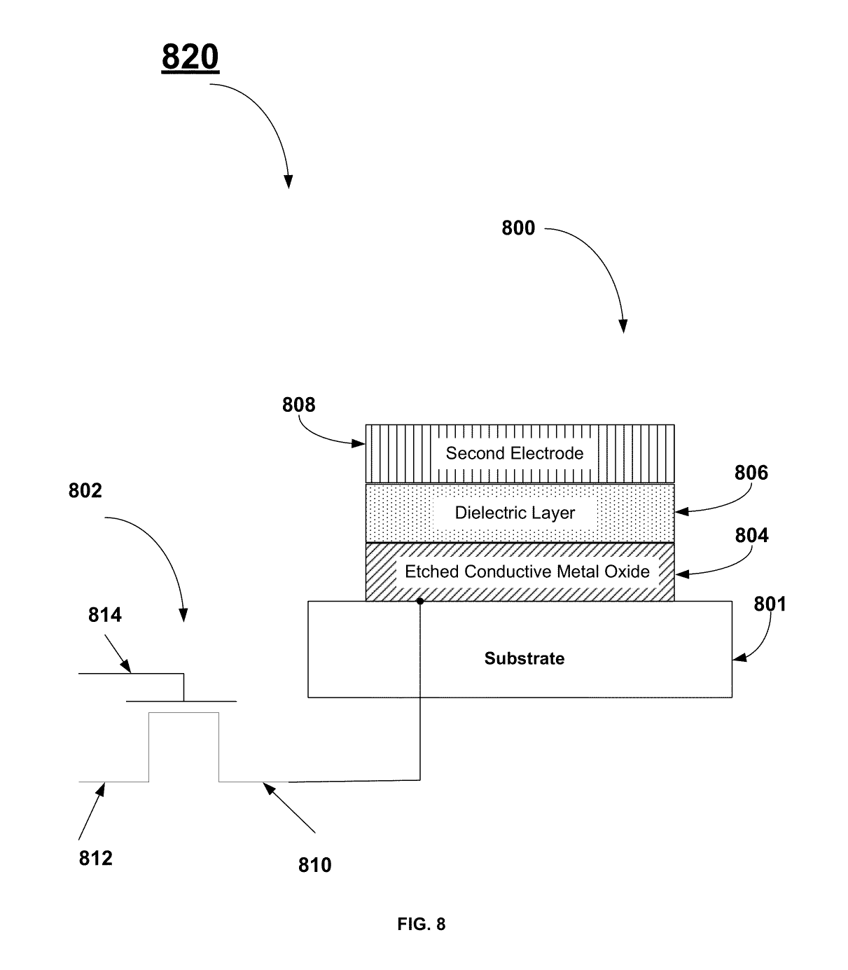

An example of a specific application of some embodiments of the present invention is in the fabrication of capacitors used in the memory cells in DRAM devices. DRAM memory cells effectively use a capacitor to store charge for a period of time, with the charge being electronically “read” to determine whether a logical “one” or “zero” has been stored in the associated cell. Conventionally, a cell transistor is used to access the cell. The cell transistor is turned “on” in order to store data on each associated capacitor and is otherwise turned “off” to isolate the capacitor and preserve its charge. More complex DRAM cell structures exist, but this basic DRAM structure will be used for illustrating the application of this disclosure to capacitor manufacturing and to DRAM manufacturing. FIG. 8 is used to illustrate one DRAM cell, 820, manufactured using a doped high k material as discussed previously. The cell, 820, is illustrated schematically to include two principle components, a cell capacitor, 800, and a cell transistor, 802. The cell transistor is usually constituted by a MOS transistor having a gate, 814, source, 810, and drain, 812. The gate is usually connected to a word line and one of the source or drain is connected to a bit line. The cell capacitor has a lower or storage electrode and an upper or plate electrode. The storage electrode is connected to the other of the source or drain and the plate electrode is connected to a reference potential conductor. The cell transistor is, when selected, turned “on” by an active level of the word line to read or write data from or into the cell capacitor via the bit line.

As was described previously in connection with FIGS. 1-3, the cell capacitor, 800, comprises a first electrode, 804, formed on substrate, 801. The first electrode, 804, is connected to the source or drain of the cell transistor, 802. For illustrative purposes, the first electrode has been connected to the source, 810, in this example. For the purposes of illustration, first electrode, 804, will be MoO₂ in this example. As discussed previously, first electrode, 804, may be etched and then subjected to an anneal in a reducing atmosphere or an inert atmosphere (i.e. N₂ or Ar) before the formation of the dielectric layer to crystallize the MoO₂ and to remove or reduce any MoO₂₊ₓ compounds that may have formed during the formation of the first electrode. A high k dielectric material, 806, is formed on top of the first electrode. For the purposes of illustration, doped high k material, 806, will be TiO₂ doped with Al. Typically, the doped TiO₂ material is then subjected to a PDA treatment. The second electrode, 808, is then formed on top of the doped TiO₂ material. For the purposes of illustration, the second electrode, 808, may be TiN, MoO₂, Ru, or doped-SnO₂ in this example. Although FIG. 8 illustrates a conductive metal oxide first electrode, the same discussion would hold for a conductive metal oxide used as a second electrode (not shown). The bottom portion of the second electrode (i.e. in contact with the dielectric layer) would be the bulk conductive metal oxide layer and a low density metal oxide layer would form the top portion of the second electrode. As outlined in the methods described in FIG. 2 and FIG. 3, the second electrode can also be subjected to an etch step to remove the low density portion before being annealed. This completes the formation of the capacitor stack. Typically, the capacitor stack is then subjected to a PMA treatment.

Although various embodiments that incorporate the teachings of the present invention have been shown and described in detail herein, those skilled in the art can readily devise many other varied embodiments that still incorporate these teachings.

1. A method for fabricating a capacitor stack, the method comprising:
forming a first electrode layer on a substrate, the first electrode layer comprising a conductive metal oxide;
etching a surface of the first electrode layer,
wherein etching comprises reducing a thickness of the first electrode layer by removing a top portion of the first electrode layer throughout the entire surface of the first electrode layer;
annealing the first electrode layer in a reducing atmosphere or an inert atmosphere;
forming a dielectric layer on the first electrode layer; and
forming a second electrode layer on the dielectric layer.

2. The method of claim 1, wherein the etching is one of a wet etch technique, a reactive ion etching technique, or an ion milling technique.

3. The method of claim 1, wherein the annealing of the first electrode is performed in an atmosphere comprising one of H2/N2, H2/Ar, N2, or Ar.

4. The method of claim 1, wherein the annealing is performed at a temperature between about 400 C to about 650 C.

5. The method of claim 1, wherein the annealing is performed using one of thermal energy, plasma energy, or rapid thermal annealing.

6. The method of claim 1 wherein the conductive metal oxide is molybdenum oxide, wherein at least about 40% of the molybdenum oxide is present as crystalline MoO2 after the etching and the annealing.

7. The method of claim 1 wherein the dielectric layer is titanium dioxide, wherein at least about 30% of the titanium dioxide is present in the rutile crystalline phase.

8. The method of claim 1, wherein the second electrode layer comprises one of a metal, a conductive metal oxide, a conductive metal nitride, a conductive metal silicide, or mixtures thereof.

9. The method of claim 8 further comprising etching the surface of the second electrode.

10. The method of claim 9 wherein the etching is one of a wet etch technique, a reactive ion etching technique, or an ion milling technique.

11. The method of claim 9 further comprising annealing the second electrode after the etching.

12. The method of claim 11, wherein the annealing is performed at a temperature between about 400 C to about 650 C.

13. The method of claim 11, wherein the annealing is performed using one of thermal energy, plasma energy, or rapid thermal annealing.

14. The method of claim 11 wherein the conductive metal oxide is molybdenum oxide, wherein at least about 40% of the molybdenum oxide is present as crystalline MoO₂ after the etching and the annealing.

15. A method for fabricating an electrode, the method comprising:
forming a layer on a substrate, the layer comprising a conductive metal oxide;
etching a surface of the layer,
wherein etching comprises reducing a thickness of the layer by removing a top portion of the layer throughout the entire surface of the layer; and
annealing the layer in a reducing atmosphere or an inert atmosphere.

16. The method of claim 15, wherein the etching is one of a wet etch technique, a reactive ion etching technique, or an ion milling technique.

17. The method of claim 15, wherein the annealing of the electrode is performed in an atmosphere comprising one of H₂/N₂, H₂/Ar, N₂ or Ar.

18. The method of claim 15, wherein the annealing is performed at a temperature between about 400 C to about 650 C.

19. The method of claim 15, wherein the annealing is performed using one of thermal energy, plasma energy, or rapid thermal annealing.

20. The method of claim 15, wherein the conductive metal oxide is molybdenum oxide, wherein at least about 40% of the molybdenum oxide is present as crystalline MoO₂ after the etching and the annealing.
